(19) United States
(12) Patent Application Publication
(10) Pub. No.: US 2007/0215327 A1
(43) Pub. Date: Sep. 20, 2007

(54) HEAT DISSIPATION DEVICE

(76) Inventors: Cheng-Tien Lai, Shenzhen (CN); Zhi-Yong Zhou, Shenzhen (CN); Jian Hu, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/308,282

(22) Filed: Mar. 15, 2006

(51) Int. Cl. H05K 7/20

(52) U.S. Cl. 165/104.33; 165/80.3; 361/700; 257/715

(57) ABSTRACT

A heat dissipation device includes a heat sink (30) and a heat pipe (40) thermally attached to the heat sink. The heat sink includes a base (32) with an opening (3262) defined therethrough, and a plurality of fins (36) mounted on the base. The heat pipe comprises an evaporating portion (42) and a condensing portion (44) thermally connecting with the fins. The evaporating portion comprises a flat bottom surface (422) for directly contacting with an electronic unit (50) and an arc-shaped top surface (424) contacting with the fins at the opening of the base.

### FIELD OF THE INVENTION

The present invention relates to a heat dissipation device, and more particularly to a heat dissipation device including a heat sink and heat pipes for achieving a better heat dissipation efficiency.

### DESCRIPTION OF RELATED ART

As computer technology continues to advance, electronic components such as central processing units (CPUs) of computers are made to provide faster operational speeds and greater functional capabilities. When a CPU operates at a high speed in a computer enclosure, its temperature usually increases enormously. It is desirable to dissipate the generated heat of the CPU quickly.

Conventionally, a heat dissipation device is used to dissipate heat generated by a CPU. Referring to FIGS. 7-8, a conventional heat dissipation device comprises a heat sink 100 and a pair of heat pipes 200 thermally contacting with the heat sink 100. The heat sink 100 is made of metal material with good heat conductivity and comprises two spaced flat bases 102 each defining two holes therein, and a plurality of fins 104 extending uprightly from the lower base 102 to the upper base 102. The lower base 102 is for contacting with a CPU 300. The heat pipe 200 is U-shaped. Two ends of each heat pipes 200 extend into the corresponding holes of the two bases 102. When the heat dissipation device is used, the lower base 102 contacting with the CPU 300 absorbs heat from the CPU 300. Part of the heat accumulated at the lower base 102 is transferred to a bottom portion of the fins 104 to create a first heat transfer path, while the other part of the heat is transferred to the upper base 102 through the heat pipes 200 to create a second heat transfer path. However, in the second heat transfer path, the heat generated by the CPU 300 is transferred to the heat pipes 200 through the lower metal base 102; it is well known that a metal stock has a higher heat resistance than that of the heat pipes 200. Therefore, the heat generated by the CPU 300 can not be transmitted to the heat pipes 200 efficiently, whereby the heat dissipation device cannot have a high heat dissipation efficiency.

What is needed, therefore, is a heat dissipation device, which can overcome above-described disadvantage of the conventional heat dissipation device.

### SUMMARY OF INVENTION

A heat dissipation device comprises a heat sink and a heat pipe thermally attached to the heat sink. The heat sink comprises a base with an opening defined therethrough, and a plurality of fins mounted on the base. The heat pipe comprises an evaporating portion and a condensing portion thermally connecting with the fins. The evaporating portion comprises a flat bottom surface for directly contacting with an electronic unit and an arc-shaped top surface contacting with the fins at the opening of the base.

Other advantages and novel features will become more apparent from the following detailed description of preferred embodiments when taken in conjunction with the accompanying drawings, in which:

### BRIEF DESCRIPTION OF DRAWINGS

FIG. 1 is a perspective view of a heat dissipation device in accordance with a preferred embodiment of the present invention;

FIG. 2 is similar to FIG. 1, but viewed from a different aspect with a heat pipe removed away to clearly show a bottom structure of the heat dissipation device;

FIG. 3 is an exploded view of FIG. 2;

FIG. 4 is an enlarged view of a base of FIG. 3;

FIG. 5 is a cross-sectional view taken along a line V-V of FIG. 1, together with a CPU mounted on a printed circuit board;

FIG. 6 is a cross-sectional view of a heat dissipation device in accordance with another preferred embodiment of the present invention;

FIG. 7 is an isometric view of a conventional heat dissipation device; and

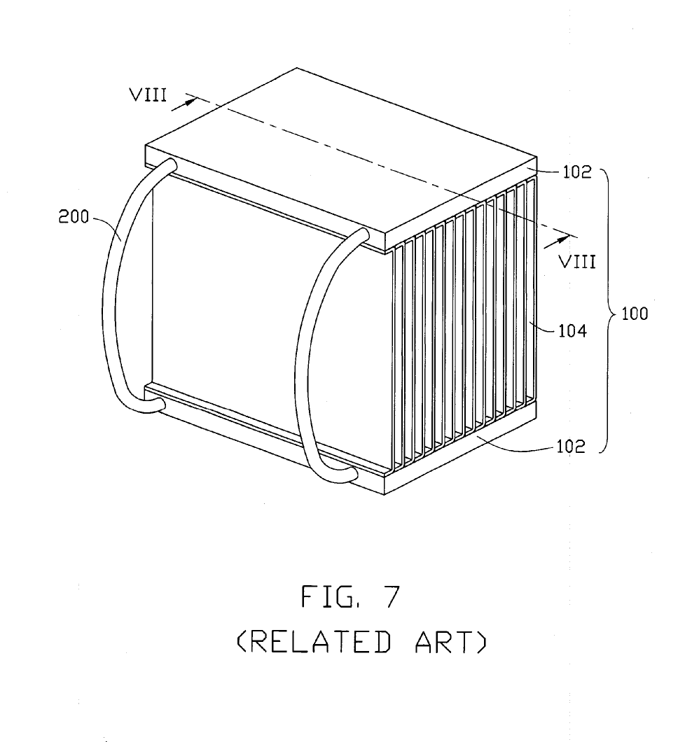

FIG. 8 is a cross-sectional view taken along a line VIII-VIII of FIG. 7.

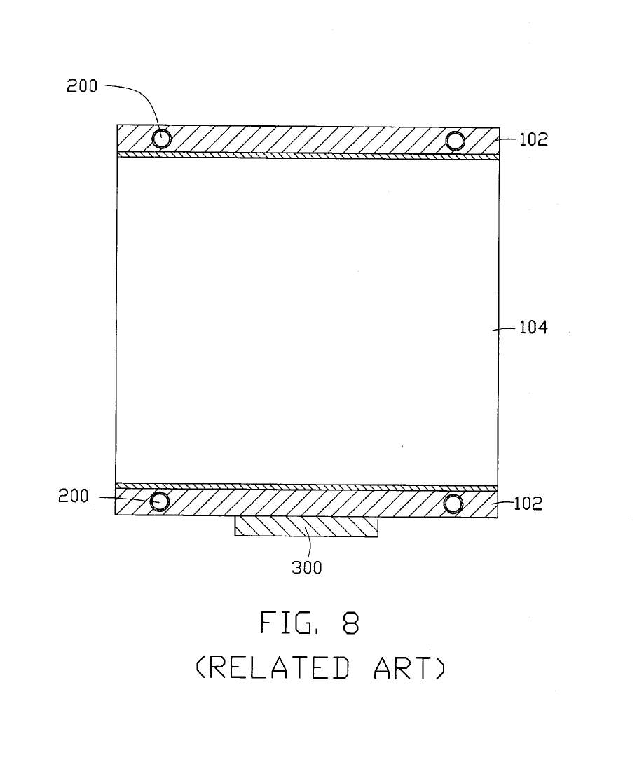

### DETAILED DESCRIPTION

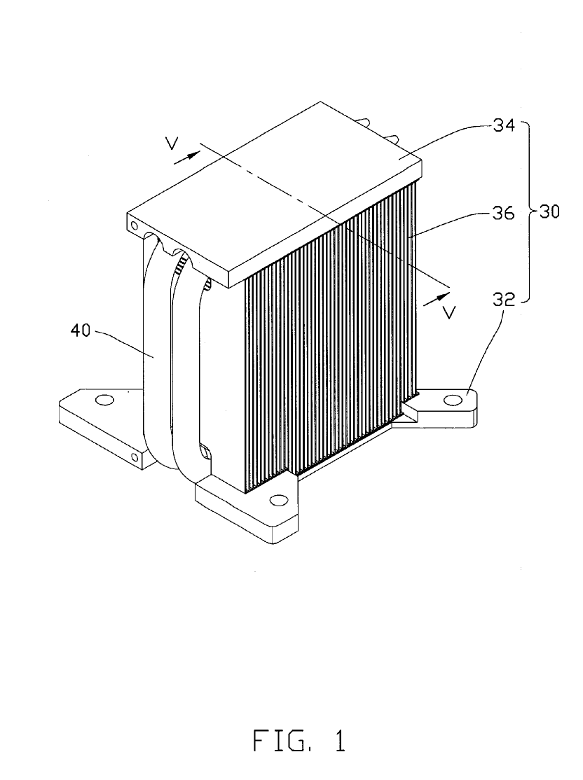

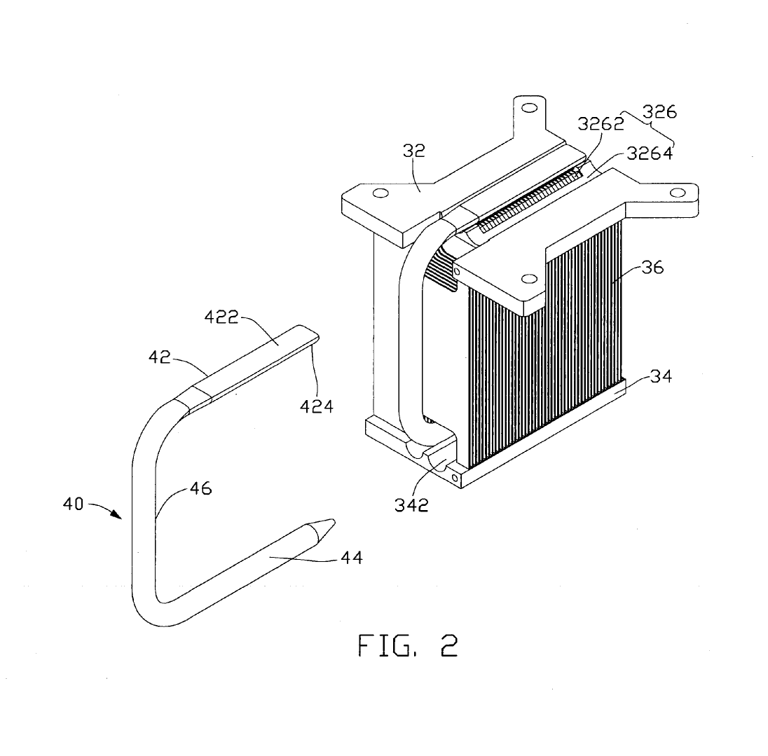

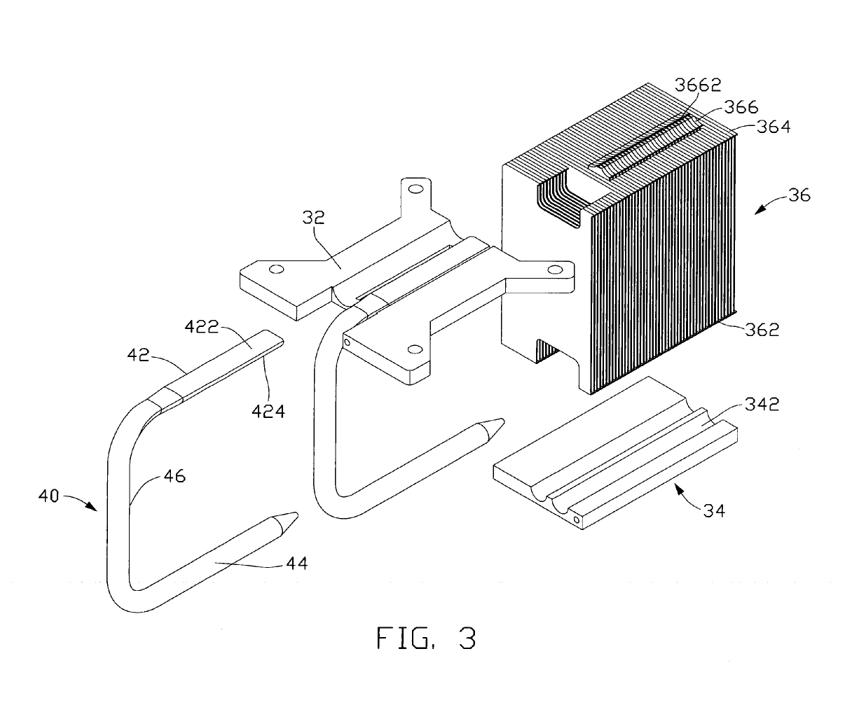

Referring to FIGS. 1-3, a heat dissipation device in accordance with a preferred embodiment of the invention comprises a heat sink 30 and two heat pipes 40 thermally connecting with the heat sink 30.

The heat sink 30 comprises a base 32, a cover 34 spaced from and parallel to the base 32, and a plurality of fins 36 extending between the base 32 and the cover 34.

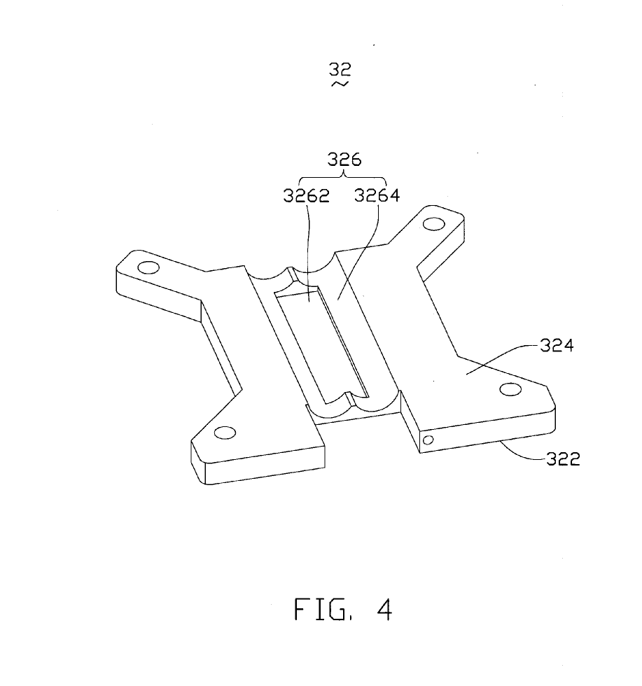

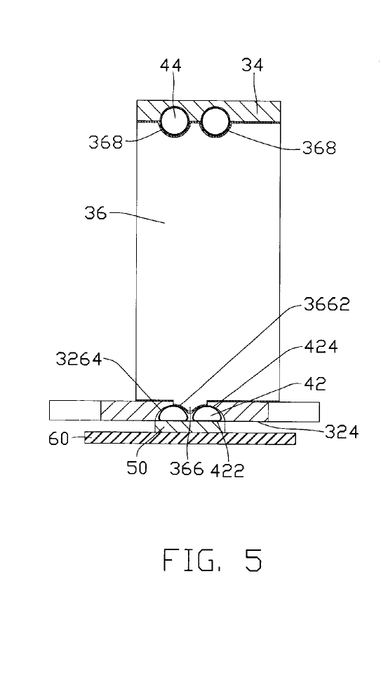

Referring also to FIG. 4, the base 32 is made of heat conductive material such as cooper or aluminum. The base 32 is used for securing the heat dissipation device to a CPU 50 mounted on a printed circuit board 60 (FIG. 5). The base 32 has a top surface 322 facing a bottom surface 364 of the fins 36, and a bottom surface 324 opposite to the top surface 322 and facing the CPU 50. A concave portion 326 is defined in a center portion of the bottom surface 324 of the base 32. The concave portion 326 includes a rectangular opening 3262 defined through a center of the base 32, and a pair of grooves 3264 beside the opening 3262. The grooves 3264 are in communication with opposite sides of the rectangular opening 3262, respectively. The grooves 3264 are designed for fittingly receiving first heat-conducting portions 42 (i.e., evaporating portions) of the heat pipes 40 therein. Each groove 3264 has a curved surface matching with a top surface 424 of the first heat-conducting portions 42 of the heat pipe 40, whereby the first heat-conducting portions 42 can be fittingly received in the grooves 3264 and have an intimate contact with the base 32.

The cover 34 defines a pair of parallel grooves 342 extending from one side thereof to an opposite side. Opposite top and bottom edges of the fins 36 are bent to form a plurality of heat conducting flanges (not labeled). The heat conducting flanges cooperatively form top and bottom surfaces 362, 364 of the fins 36. The bottom surface 364 of the fins 36 is attached to the top surface 322 of the base 32. A generally triangular projection 366 extends from the bottom surface 364 of the fins 36 towards the base 32, which can project through the rectangular opening 3262 of the base 32 to contact with the first heat-conducting portions 42 of the heat pipes 40. The generally triangular projection 366 has a pair of arc-shaped side surfaces 3662 matching with the top surfaces 424 of the first heat-conducting portions 42 of the heat pipe 40 for closely contacting the heat pipes 40 to reduce heat resistance therebetween. A pair of grooves 368 (see FIG. 5) is defined in the top surface 362 of the fins 36 aligned with the grooves 342 of the cover 34. The grooves 368 of the fins 36 and the grooves 342 of the cover 34 cooperatively form two passages for accommodating corresponding second heat-conducting portions 44 (i.e. condensing portions) of the heat pipes 40, respectively.

Each heat pipe 40 has a U-shaped configuration, and forms a capillary structure therein. A quantity of working medium such as water is contained in the heat pipes 40. Referring to FIG. 5, the first heat-conducting portion 42 is used for absorbing heat from the CPU 50. The first heat-conducting portion 42 has a flat bottom surface 422 and an arc-shaped top surface 424. When the heat pipes 40 and the heat sink 30 are assembled together, the bottom surface 422 of the first heat-conducting portion 42 and the bottom surfaces 324 of the base 32 are positioned in a same plane, whereby the bottom surface 422 of the first heat-conducting portion 42 can directly contact with the CPU 50 for directly absorbing heat from the CPU 50. The triangular projection 366 of the fins 36 extends through the rectangular opening 3262 of the base 32 into the grooves 3264 to enable parts of the top surfaces 424 of the first heat-conducting portions 42 to contact with corresponding arc-shaped side surfaces 3662 of the triangular projection 366, respectively. The other parts of the top surfaces 424 of the first heat-conducting portions 42 fittingly engage in the grooves 3264 of the base 32, respectively, and thermally contact with the base 32. The top surfaces 424 of the first heat-conducting portions 42 simultaneously contacts with the base 32 and the projection 366 of the fins 36. The second heat-conducting portions 44 of the heat pipes 40 are received in the passages formed by the grooves 368 of the fins 36 and the grooves 342 of the cover 34. The second heat-conducting portions 44 are used for dissipating the heat from the first heat-conducting portions 42 to the cover 34 and the fins 36. Each heat pipe 40 further comprises a third portion 46 interconnecting the first and second heat-conducting portions 42, 44 together. The working medium circuits between the first and second heat-conducting portions 42, 44 along the third portion 46 to transfer the heat from the first heat-conducting portion 42 to the second heat-conducting portion 44.

In use of the heat dissipation device, heat produced by the CPU 50 is directly absorbed by the first heat-conducting portions 42 of the heat pipes 40. Part of the heat accumulated at the heat pipes 40 is directly transferred to the projection 366 of the fins 36 that contacts the top surface 424 of the first heat-conducting portions 42 of the heat pipes 40 to create a first heat transfer path. Another part of the heat is directly transferred to the base 32 and then the fins 36 to create a second heat transfer path. The other part of the heat is directly transferred to the cover 34 and the heat conducting flanges of the fins 36 contacting with the second heat-conducting portions 44 of the heat pipes 40 to create a third heat transfer path.

The heat produced by the CPU 50 is directly conducted to the first heat-conducting portions 42 of the heat pipes 40, and then transferred to the base 32, the cover 34 and the fins 36 in three heat transfer paths, respectively. The heat resistance between the heat pipes 40 and the CPU 50 is greatly reduced in comparison with the related art. Furthermore, there are three heat transfer paths for removing heat from the CPU 50 away simultaneously. This can accelerate the speed of heat dissipation to improve the heat dissipation efficiency. Additionally, the first heat-conducting portion 42 has an arc-shaped top surface 424 for increasing the contacting areas between the heat pipe 40 and other heat transfer components such as the base 32 and the fins 36. The first heat-conducting portion 42 further has a flat bottom surface 422, which directly contacts with the CPU 50 with a large area. Thus, heat produced by the CPU 50 can be quickly transferred to the base 32 and the fins 36 to further improve the heat dissipation efficiency of the heat dissipation device of the present invention.

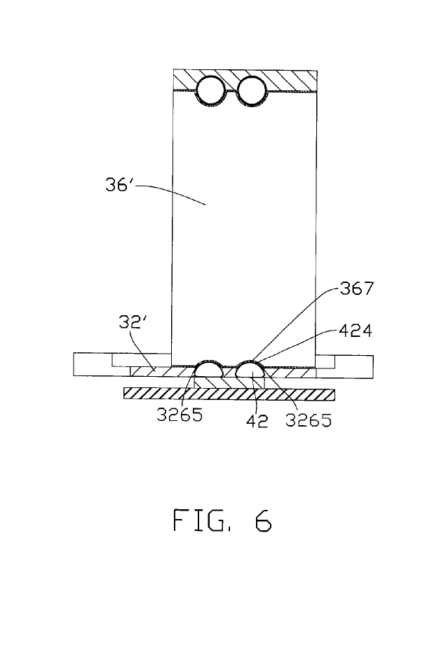

FIG. 6 shows a cross-sectional view of a heat dissipation device in accordance with another preferred embodiment of the present invention. The main difference between the embodiment shown in FIG. 6 and that of FIG. 5 is that a pair of slots 3265 is defined through the base 32′. The slots 3265 are so shaped and dimensioned that when the first heat-conducting portions 42 of the heat pipes 40 are received in the slots 3265, upper portions (not labeled) of the arc-shaped top surfaces 424 of the first heat-conducting portions 42 of the heat pipes 40 extend upwardly through the slots 3265 to be received in grooves 367 defined in a bottom portion of the fins 36′, respectively. The upper portions of the arc-shaped top surfaces 424 of the first heat-conducting portions 42 of the heat pipes 40 engage with the fins 36′. Lower portions of the arc-shaped top surfaces 424 of the first heat-conducting portions 42 of the heat pipes 40 engage with the base 32′. Other elements of this embodiment are similar to the first preferred embodiment and thus their detailed description is omitted herewith.

In the preferred embodiments of the present invention, the connection between the heat pipes 40 and the base 32, between the heat pipes 40 and the cover 34, and between the heat pipes 40 and the fins 36 is achieved by soldering thus they are both mechanically and thermally connected together.

Alternatively, the second heat-conducting portions 44 of the heat pipes 40 can extend through and connect the fins 36 without use of the cover 34. In addition, the number of the heat pipe 40 is not limited to two; one heat pipe 40 or more than two heat pipes 40 can be used, which is based on the quantity of heat produced by the CPU 50.

It can be understood that the heat pipe 40 can be other alternative structures, such as S-shaped heat pipe having an evaporating portion and two parallel condensing portions, so far as the evaporating portion can directly contact with the CPU, and the condensing portion can contact with the portions of the fins located away from the CPU.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a heat sink comprising a base with an opening defined therethrough, and a plurality of fins mounted on the base; and
a heat pipe attached to the heat sink, the heat pipe comprising an evaporating portion and a condensing portion thermally connecting with the fins, the evaporating portion comprising a flat bottom surface for directly contacting with an electronic unit and an arc-shaped top surface contacting with the fins at the opening of the base.

2. The heat dissipation device as claimed in claim 1, wherein the flat bottom surface of the heat pipe is coplanar with a bottom surface of the base.

3. The heat dissipation device as claimed in claim 1, wherein a groove is defined in a portion of the fins adjacent to the base, and the arc-shaped top surface of the evaporating portion of the heat pipe extends upwardly through the opening of the base and is received in the groove of the fins.

4. The heat dissipation device as claimed in claim 1, wherein the base further comprises a concave portion, and the opening is defined in the concave portion.

5. The heat dissipation device as claimed in claim 4, wherein the concave portion comprises a groove extending in one side of the concave portion, the groove of the concave portion communicating with the opening and receiving a part of the arc-shaped top surface of evaporating portion of the heat pipe therein.

6. The heat dissipation device as claimed in claim 5, wherein the part of the arc-shaped top surface of the evaporating portion of the heat pipe is fittingly received in the groove of the concave portion.

7. The heat dissipation device as claimed in claim 5, wherein the fins comprise a projection extending through the opening for directly contacting with another part of the arc-shaped top surface of the evaporating portion of the heat pipe.

8. The heat dissipation device as claimed in claim 7, wherein the projection comprises an arc-shaped side surface engaging with the another part of the arc-shaped top surface of the evaporating portion of the heat pipe.

9. The heat dissipation device as claimed in claim 1, wherein the heat sink further comprises a cover parallel to the base, and the fins extends between the base and the cover.

10. The heat dissipation device as claimed in claim 9, wherein the cover and the fins cooperatively define a passage for accommodating the condensing portion of the heat pipe.

11. The heat dissipation device as claimed in claim 9, wherein the heat pipe is U-shaped, and two ends of the heat pipe form the evaporating portion and the condensing portion, respectively.

12. A heat dissipation device comprising:
a base comprising a groove defined in a bottom portion thereof, and an opening defined through the base and in communication with the groove;
a plurality of fins mounted on the base, the fins comprising a projection extending through the opening; and
a heat pipe comprising an evaporating portion accommodated in the groove and contacting with the projection of the fins, and a condensing portion thermally connecting with the fins.

13. The heat dissipation device as claimed in claim 12, wherein the evaporating portion comprising a flat bottom surface for directly contacting with an electronic unit and an arc-shaped top surface contacting with the projection of the fins.

14. The heat dissipation device as claimed in claim 13, wherein the projection of the fins comprises a side surface matching and contacting with the arc-shaped top surface of the evaporating portion of the heat pipe.

15. The heat dissipation device as claimed in claim 13, wherein a part of the arc-shaped top surface of the evaporating portion of the heat pipe fittingly engages in the groove.

16. An electronic assembly comprising:
a heat-generating electronic component;
a base on the electronic component;
a plurality of fins mounted on the base for dissipating heat generated by the electronic component;
a heat pipe having an evaporating portion received in the base and contacting with the electronic component, the base and the fins, and an condensing portion extending from the evaporating portion to thermally connect with the fins.

17. The electronic assembly as claimed in claim 16, wherein the evaporating portion has a flat bottom surface contacting with the electronic component and an arc-shaped top surface contacting with the base and the fins.

18. The electronic assembly as claimed in claim 17, wherein the arc-shaped top surface of the evaporating portion of the heat pipe extends upwardly through the base to contact with the fins.

19. The electronic assembly as claimed in claim 17, wherein the fins have a projection extending downwardly into the base to contact with the arc-shaped top surface of the evaporating portion of the heat pipe.

20. The electronic assembly as claimed in claim 19, wherein the base defines an opening and a groove beside the opening, the evaporating portion of the heat pipe is fittingly received in the groove, and the projection of the fins extends through the opening into the base to contact with the arc-shaped top surface of the evaporating portion of the heat pipe.
